(19) United States
(12) Patent Application Publication
(10) Pub. No.: US 2025/0284202 A1
(43) Pub. Date: Sep. 11, 2025

(54) PHOTOLITHOGRAPHIC MASK PATTERN ADJUSTMENT AND DEVICES FABRICATED THEREFROM

(71) Applicant: TEXAS INSTRUMENTS INCORPORATED, Dallas, TX (US)

(72) Inventors: Yi-Hao Huang, Dallas, TX (US); Abhishek Asthana, San Jose, CA (US); Gerard Luk-Pat, Dallas, TX (US); Jakin Delony, McKinney, TX (US); Scott Jessen, Allen, TX (US)

(21) Appl. No.: 18/758,632

(22) Filed: Jun. 28, 2024

Related U.S. Application Data
(60) Provisional application No. 63/562,830, filed on Mar. 8, 2024.

(51) Int. Cl. G03F 7/00

(52) U.S. Cl. CPC G03F 7/70441; G03F 7/705; G03F 7/70516

(57) ABSTRACT

A method of fabricating a semiconductor device includes determining, based on first data including measurement data associated with formation of geometric features using a first mask pattern and second data characterizing deviations in the formation of the geometric features using the first mask pattern, third data that characterizes contributing factors to the deviations. The third data is determined utilizing at least one machine learning algorithm. The method calibrates an optical proximity correction model based on the third data and uses the calibrated model to tune an optical proximity correction process to compute adjustments to mask features of the first mask pattern to form a second mask pattern that compensates for at least a portion of the deviations in the formation of the geometric features using the first mask pattern. The method includes forming the geometric features in a semiconductor layer utilizing a photolithographic mask device having the second mask pattern.

### CROSS-REFERENCE TO RELATED APPLICATIONS

This application claims the benefit of and priority to U.S. Provisional Application No. 63/562,830, filed Mar. 8, 2024, the disclosure of which is incorporated by reference herein in its entirety.

### TECHNICAL FIELD

The present disclosure relates to the field of photolithography, and more particularly to photolithographic masks and devices fabricated using such photolithographic masks.

### BACKGROUND

Photolithography is a frequently used process in semiconductor and other device fabrications. While some photolithography techniques are maskless, where light is applied directly to a photosensitive material of a photoresist layer formed on a semiconductor or other layer of the device being fabricated, other photolithography techniques utilize a mask device (referred to, e.g., as a mask or reticle). In the latter case, light is shone onto a surface of the mask device positioned between the light source and the semiconductor device being fabricated. Based on a mask pattern formed on a surface of the mask device, light passes through the mask device to the photoresist layer in certain areas while being blocked in other areas.

A mask device can be a clear field mask or a dark field mask. In a clear field mask, the patterned features on a surface of the mask device block light while the other surface areas pass light. Conversely, in a dark field mask, the patterned features pass light, while the other surface areas block light. Still further, the underlying photoresist layer formed on the device being fabricated can be positive or negative. In a positive photoresist, portions of the photosensitive material are removed when exposed to light and developed. Conversely, in a negative photoresist, portions of the photosensitive material are removed when developed unless exposed to light.

A profile is thereby formed in the photoresist layer based on the mask pattern and then transferred to the underlying layer of the device being fabricated to form one or more geometric features (e.g., structures or portions of structures) therein.

### SUMMARY

The present disclosure describes mask patterns and mask devices for photolithography used in semiconductor and other device fabrication. This summary is not an extensive overview of the disclosure. Rather, a purpose of the summary is to present some examples of the present disclosure in a simplified form as a prelude to a more detailed description that is presented later.

In some examples, a method includes obtaining first data, where the first data includes measurement data associated with a formation of one or more geometric features in a semiconductor layer using a photolithographic mask device, the photolithographic mask device having a first mask pattern including one or more mask features designed to form the one or more geometric features. The method also includes obtaining second data based on the first data, where the second data characterizes one or more deviations in the formation of the one or more geometric features. The method further includes determining third data based on the first data and the second data, where the third data characterizes one or more contributing factors to the one or more deviations, and where the third data is automatically determined using at least one machine learning algorithm. The method further includes computing one or more adjustments to the one or more mask features of the first mask pattern, using at least a portion of the third data, to generate a second mask pattern, wherein the second mask pattern compensates for at least a portion of the one or more deviations in the formation of the one or more geometric features.

In some other examples, an apparatus includes at least one processor and at least one memory storing instructions that, when executed by the at least one processor, cause the apparatus to obtain first data, wherein the first data includes measurement data associated with a formation of one or more geometric features in a semiconductor layer using a photolithographic mask device, the photolithographic mask device having a first mask pattern including one or more mask features designed to form the one or more geometric features. The instructions, when executed by the at least one processor, also cause the apparatus to obtain second data based on the first data, wherein the second data characterizes one or more deviations in the formation of the one or more geometric features. The instructions, when executed by the at least one processor, further cause the apparatus to determine third data based on the first data and the second data, wherein the third data characterizes one or more contributing factors to the one or more deviations, wherein the third data is automatically determined using at least one machine learning algorithm. The instructions, when executed by the at least one processor, further cause the apparatus to compute one or more adjustments to the one or more mask features of the first mask pattern, using at least a portion of the third data, to generate a second mask pattern, wherein the second mask pattern compensates for at least a portion of the one or more deviations in the formation of the one or more geometric features.

In some additional examples, a method of fabricating a semiconductor device includes determining, based on (i) first data including measurement data associated with formation of one or more geometric features using a first mask pattern including one or more mask features and (ii) second data characterizing one or more deviations in the formation of the one or more geometric features using the first mask pattern, third data utilizing at least one machine learning algorithm, the third data characterizing one or more contributing factors to the one or more deviations. The method also includes calibrating an optical proximity correction model based on the third data. The method further includes using the calibrated optical proximity correction model to tune a corresponding optical proximity correction process to compute one or more adjustments to the one or more mask features of the first mask pattern to form a second mask pattern, the second mask pattern compensating for at least a portion of the one or more deviations in the formation of the one or more geometric features using the first mask pattern. The method still further includes forming the one or more geometric features in a semiconductor layer utilizing a photolithographic mask device having the second mask pattern.

### BRIEF DESCRIPTION OF THE DRAWINGS

FIG. 1 is a block diagram of a mask device fabrication in accordance with an example of the present disclosure;

FIG. 2 is a block diagram of a process for patterning a photoresist layer utilizing a mask device in accordance with an example of the present disclosure;

FIG. 3 is a block diagram of a process for adjusting a mask pattern utilizing an optical proximity correction system in accordance with an example of the present disclosure;

FIG. 4 are graphic diagrams of mask patterns and semiconductor layers depicting patterning with and without optical proximity correction model adjustment in accordance with examples of the present disclosure;

FIGS. 5A-9 are flow diagrams of methodologies for machine learning-driven calibration of an optical proximity correction model in accordance with examples of the present disclosure;

FIG. 10 is a flow diagram of a methodology for machine learning-driven computation of adjustments to mask features of mask patterns of photolithographic mask devices used to form geometric features in semiconductor layers in accordance with examples of the present disclosure;

FIG. 11 is a block diagram of a computer system with which one or more examples of the present disclosure can be implemented; and

FIG. 12 is a block diagram of a distributed communications/computing network with which one or more examples of the present disclosure can be implemented.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, photolithographic mask devices are used to form one or more structures in a semiconductor device or other types of devices. For example, photolithographic techniques have been proposed to enable fabrication of structures with two-dimensional (2D) shaping, e.g., linear-based shapes defined in x and y dimensions on a plane where the structures have substantially perpendicular sidewalls in a z dimension orthogonal to the plane. Other forms of photolithography, e.g., grayscale photolithography, have been proposed to facilitate three-dimensional (3D) structure shaping, e.g., structures defined in x and y dimensions on a plane with non-perpendicular (e.g., sloped, tapered, contoured) sidewall profiles.

More particularly, grayscale mask-based lithography uses a mask device (e.g., sometimes referred to as a grayscale mask or grayscale reticle) to spatially modulate or modify the light intensity or dosage applied to a photoresist layer formed on an underlying layer of the device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the substrate. More particularly, grayscale mask devices rely on the concept of diffraction where light bends or spreads around the edges of the opaque areas while passing through the open areas of the patterned opaque layer.

Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material) or some portion of the applied light to pass (e.g., translucent or semitransparent material).

In a clear field mask, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The light passing through the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various geometric features (e.g., structures or portions of structures) of the semiconductor device.

Photolithographic masks or reticles, in general, function in a similar manner as described above (e.g., light passes through a patterned opaque layer of a mask device and reacts with the photoresist layer that is then developed to form a profile, the profile then being transferred into the semiconductor layer) with the exception of the intensity modulation functionality that grayscale photolithography provides to enable shaping of 3D structures with non-perpendicular features.

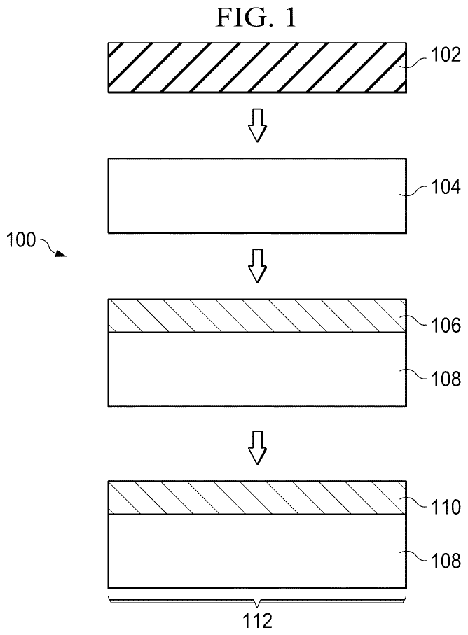

Referring now to FIG. 1, a mask device fabrication process 100 is generally shown. Initially, a mask pattern 102 is generated. In some examples, mask pattern 102 is generated using a computer-based software package such as a computer-aided design (CAD) system. The CAD system enables a designer, on a computer system with a graphical user interface, to create an image of a specific geometry of features on a layout grid that will result in a specific profile being formed in a photoresist layer. The specific profile in the photoresist layer then dictates the resulting shape (e.g., contour) of one or more corresponding geometric features in the underlying layer of the semiconductor device.

Once generated, mask pattern 102 is input to a pattern applying tool 104. For example, mask pattern 102 generated by the designer via the CAD system can be saved as a software data file that is readable by pattern applying tool 104. Pattern applying tool 104 is configured to read the mask pattern file and transfer the mask pattern 102 onto an opaque layer 106 disposed on a surface of a light-passing substrate 108 resulting in a patterned opaque layer 110, as shown in FIG. 1.

In some examples, pattern applying tool 104 is a laser-based pattern writing system. Preparation of the opaque layer 106 prior to the laser-based pattern writing process may be dependent on the particular system being used. However, in some examples, opaque layer 106 will have its own photoresist layer disposed thereon (not expressly shown) such that mask pattern 102 is applied to the photoresist layer. After development, mask pattern 102 is transferred to opaque layer 106 resulting in patterned opaque layer 110.

Accordingly, as shown in FIG. 1, a mask device 112 is fabricated including light-passing substrate 108 with the patterned opaque layer 110 disposed thereon. Patterned opaque layer 110, as mentioned above, includes opaque areas that, during semiconductor device fabrication, reflect, absorb, or otherwise block the applied light while allowing light to pass through open areas (e.g., where no opaque material is disposed) and thus through the light-passing substrate 108.

The complexity of geometric features formed in a semiconductor device using a mask device (e.g., mask device 112) is directly related to the mask pattern (e.g., mask pattern 102) formed on the mask device. Accordingly, the mask pattern dictates the positioning of the features in the patterned opaque layer (e.g., patterned opaque layer 110) of the mask device and thus the profile formed in a photoresist layer. However, the fabrication of the mask device with its mask pattern design can present technical challenges to designers, as well as to the pattern applying tools that are utilized, depending on the desired profiles and features as will be further described below.

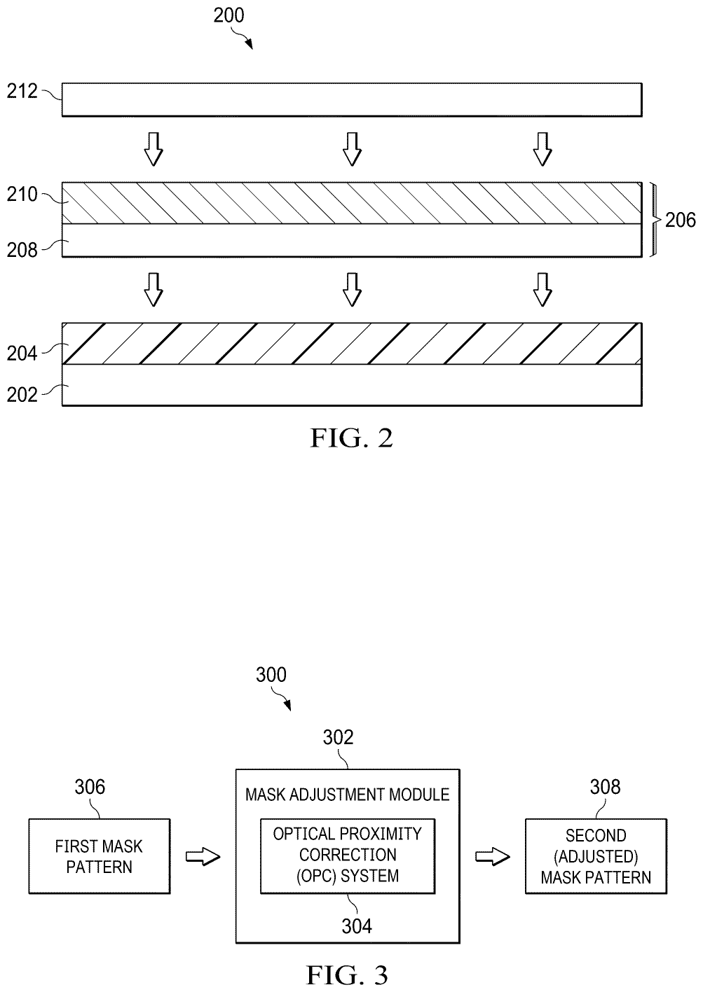

Referring now to FIG. 2, a semiconductor device fabrication process 200 is generally shown. The semiconductor device fabrication process 200 involves patterning a semiconductor layer 202. A photoresist layer 204 is formed over the semiconductor layer 202. A mask device 206 is used to create a pattern in the photoresist layer 204, with that pattern then being transferred to the underlying semiconductor layer 202. The mask device 206 includes a light-passing substrate 208 having a patterned opaque layer 210 disposed on a surface thereof. A light source 212 is applied to the mask device 206, which results in the mask pattern of the mask device 206 (e.g., defined in the patterned opaque layer 210) being transferred to the photoresist layer 204. The mask pattern can then be transferred to the semiconductor layer 202 (e.g., by etching portions of the semiconductor layer 202 which are exposed by the photoresist layer 204).

Optical Proximity Correction (OPC) technology may be used in semiconductor device fabrication processes to refine pattern accuracy of mask devices. OPC technology, for example, can refine pattern accuracy on wafers by compensating for optical distortions and process variations. In some examples, an OPC system includes an OPC model that functions in conjunction with an OPC process (sometimes also referred to as an OPC recipe) to execute the mask adjustment. In some examples, the OPC model determines, e.g., using analysis and prediction, how optical distortions and process variations affect the printing of patterns on the wafer, while the OPC process translates the predictions and other guidance from the OPC model into specific instructions for modifying the mask layout.

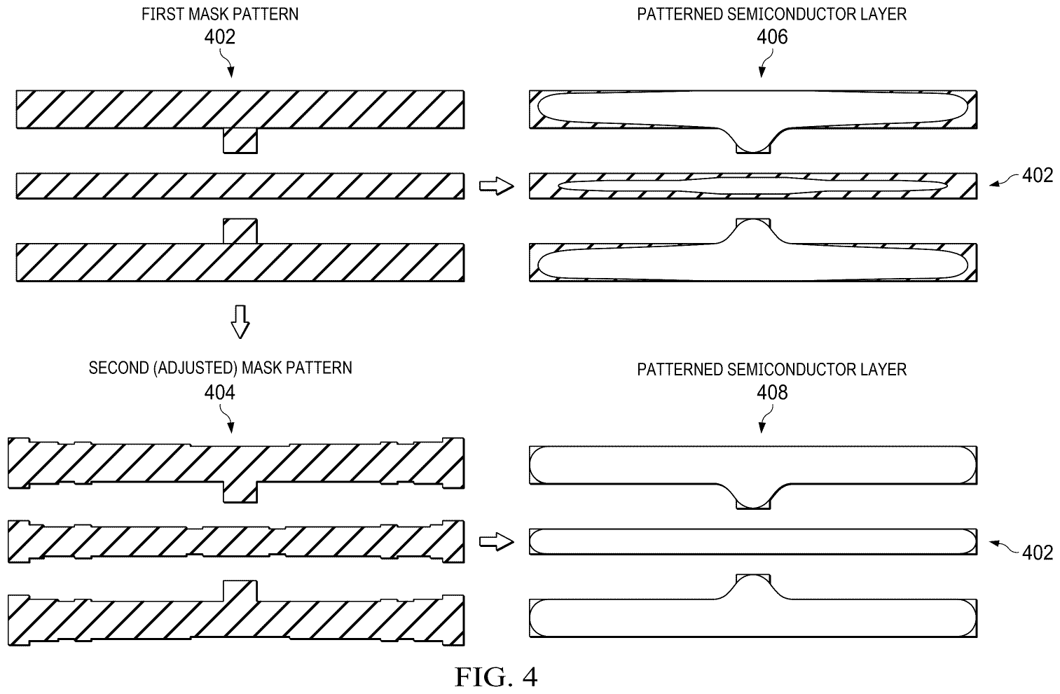

By way of example, FIG. 3 generally depicts a mask pattern adjustment process 300 wherein a mask adjustment module 302 implements an OPC system 304 (e.g., an OPC model and corresponding OPC process) configured to adjust a first mask pattern 306 to generate a second (adjusted) mask pattern 308. Second mask pattern 308 is configured to compensate for optical distortions and process variations that would otherwise affect the accuracy of features intended to be formed in a semiconductor layer when using first mask pattern 306. Patterning with and without mask pattern adjustment using an OPC system, e.g., OPC system 304, is illustrated in FIG. 4.

More particularly, FIG. 4 shows examples of patterning a semiconductor layer utilizing a first mask pattern 402 and a second (adjusted) mask pattern 404. Photolithography has limited spatial bandwidth such that, along with other optical effects and fabrication process variations, the shapes of mask features drawn or otherwise laid out by designers, e.g., in the first mask pattern 402, do not lead to the same shapes of geometric features in a semiconductor layer, e.g., the patterned semiconductor layer 406 which is patterned with a mask device using the first mask pattern 402. The first mask pattern 402 is graphically shown underneath the patterned semiconductor layer 406 to illustrate what is intended (e.g., feature shapes in the first mask pattern 402) versus what is actually formed in the semiconductor layer (e.g., feature shapes in patterned semiconductor layer 406). As is evident, the feature shapes in patterned semiconductor layer 406 do not match the intended feature shapes in the first mask pattern 402.

However, as described above, an OPC system pre-warps or otherwise modifies the designed feature shapes in the first mask pattern 402 to produce an adjusted mask pattern, e.g., the second mask pattern 404. The feature shapes in the second mask pattern 404 are modified versions (e.g., pre-warped in accordance with the OPC system) of the feature shapes in the first mask pattern 402. When patterning with a mask device utilizing the second mask pattern 404, the resulting patterned semiconductor layer 408 has feature shapes which are closer to the designed feature shapes. More particularly, as further shown in FIG. 4, the feature shapes in patterned semiconductor layer 408 more accurately match the intended feature shapes of the first mask pattern 402 graphically shown underneath the patterned semiconductor layer 408.

Moreover, determining how to pre-warp mask features using the OPC system (e.g., how to modify the feature shapes of the first mask pattern 402 to form the feature shapes of the second mask pattern 404) is based on an input design that includes both content (e.g., a target segment such as a selected one of the segments of the feature shapes of first mask pattern 402) and context (e.g., other segments or polygons such as the resulting segment in the feature shapes of second mask pattern 404 corresponding to the target segment). Edge segmentation and selected evaluation points are determined, with intensity being calculated at target points. Iterative correction is performed by segment placement and contour (e.g., the intersection of a signal value and a threshold) adjustment, to align contours with a printed critical dimension (CD). A goal of an OPC system is to minimize contour and signal error to zero.

A well-calibrated OPC system enables precise adjustments for mask patterns, influencing manufacturing success and contributing to increased yield and reliability in integrated circuit production. In semiconductor device fabrication processes, well-calibrated or otherwise robust OPC systems enable accurate photolithographic processing. Enhancing the precision of OPC systems may, in some approaches, utilize an extensive collection of Critical Dimension-Scanning Electron Microscope (CD-SEM) data and additional empirical model terms which, e.g., can lead to a prohibitive extension of the OPC system runtime.

Mask device fabrication processes are described herein that overcome the above and other technical drawbacks by utilizing a machine learning-driven mask pattern adjustment approach. In some examples, the machine learning-driven mask pattern adjustment optimizes or at least improves test pattern selection for an OPC model of an OPC system utilized in mask pattern adjustment processing. In some examples, such test pattern selection is intended to provide thorough representation and non-redundancy with respect to the test patterns selected. In some examples, machine learning-driven mask pattern adjustment optimizes or at least improves OPC model calibration time while ensuring accurate predictions for optical behavior and process variation characteristics of semiconductor device fabrication processes. The machine learning-driven mask pattern adjustment, in some examples, combines layout geometry and simulated-wafer properties, utilizes machine learning (e.g., Extreme Gradient Boost (XGBoost)) to identify photolithographic features, and clusters the feature data using Principal Component Analysis (PCA), where Gaussian Mixture Modeling (GMM) is used for clustering.

The machine learning-driven mask pattern adjustment processing, in some examples, provides effective test pattern selection through the incorporation of simulated-wafer properties alongside layout geometry properties. This integration, in some examples, emphasizes intensity features such as Maximum Intensity (Imax), Minimum Intensity (Imin), and Image Log Slope (ILS). To enhance OPC model robustness and efficiency, some examples utilize XGBoost to identify significant features affecting the target variables, which ensures inclusion of impactful features thus optimizing or at least improving the test pattern selection process. In some examples, photolithographic features are further redefined through the introduction of indicators such as, e.g., pitch², pitch³ and inverse terms related to Imax, Imin and ILS, enabling a more comprehensive understanding of photolithographic indicators' behaviors in relation to photolithographic difficulties. The term photolithographic difficulties generally refers to optical distortions, process variations, and/or other factors that may result in formation inaccuracies in features of semiconductor layers when utilizing photolithographic masks.

In some examples, a GMM machine learning clustering approach is utilized, which enables enhanced flexibility and insights into cluster characteristics on the dimensionality reduction plane. The appropriate number of clusters is determined, in some examples, using Akaike Information Criterion (AIC) and Bayesian Information Criterion (BIC) metrics, ensuring an informed and precise clustering process. Further, some examples implement uniform sampling on a remapped axis that strategically emphasizes photolithographic difficulty. Such approaches minimize or at least reduce OPC model calibration time while ensuring accurate predictions for various optical behaviors and process variation characteristics.

Machine learning-driven mask pattern adjustment processing, in some examples, selects more useful test patterns (e.g., which are both representative and non-redundant) as compared to mask pattern adjustment processes that do not use such machine learning-driven processing. Through optimizing or at least improving test pattern selection (e.g., sampling), the usage of metrology tools and OPC model calibration time can be minimized or at least reduced, while ensuring accurate prediction for various optical behaviors and process variation characteristics. In some examples, such optimized or improved sampling can be used after wafer data has been collected and before mask devices are created.

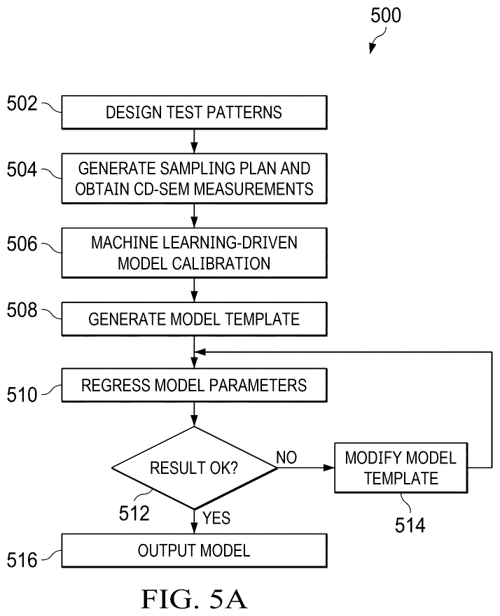

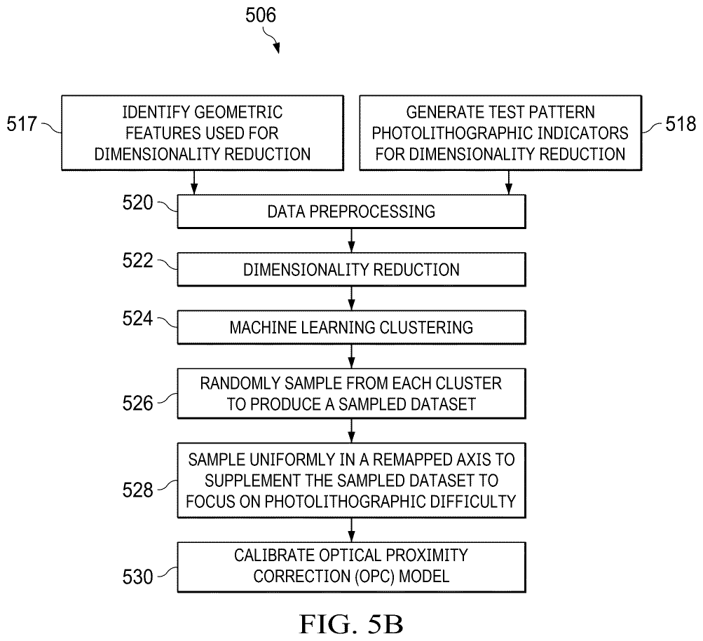

Referring now to FIG. 5A, a process flow 500 for generating an OPC model is generally shown. The process flow 500 begins with designing test patterns in block 502. The test patterns are designed for a semiconductor layer that is to be patterned. Block 502 includes factoring in design rules, e.g., After Develop Inspection (ADI) targets, Assist Feature (AF) placement, and the like. In block 504, after obtaining a mask, a sampling plan is generated and CD-SEM measurements are obtained. The sampling plan may be generated through selection of representative patterns, e.g., based on empirical engineering insights. The CD-SEM measurements are then incorporated into an Electronic Design Automation (EDA) tool for machine learning-driven model calibration in block 506. As described in further detail below, the machine learning-driven model calibration in block 506 enhances or replaces manual sampling for model calibration.

A model template for the model (e.g., an OPC model) is then generated in block 508. Model parameters are regressed in block 510. In general, model parameter regression determines relationships between model parameters, e.g., describes the relationship between one or more independent variables and a response, dependent, or target variable. In block 512, a determination is made as to whether the result is acceptable (e.g., meets design specifications). If the result of block 512 is no (e.g., does not meet one or more of the design specifications), the model template is modified in block 514 and the process flow 500 returns to block 510. If the result of block 512 is yes (e.g., does meet the design specifications), the process flow proceeds to block 516 where the model (e.g., the OPC model) is output.

Referring now to FIG. 5B, the machine learning-driven model calibration in block 506 is described in further detail. In block 517, geometric features used for dimensionality reduction are identified. Block 517, in some examples, utilizes a gradient boosting algorithm such as, e.g., XGBoost or the like. In block 518, test pattern photolithographic indicators for dimensionality reduction are generated. The photolithographic indicators, in some examples, include metrics that are based on Imax, Imin and ILS. In some examples, the photolithographic indicators include 1/(Imax−Imin), 1/ILS, [1−(Imax−Imin)]² and (1/ILS)². In block 520, the data from blocks 517 and 518 is subject to data preprocessing. The data preprocessing, in some examples, includes standardization of the identified geometric features and the generated test pattern photolithographic indicators. In block 522, dimensionality reduction is performed. The dimensionality reduction, in some examples, employs Principal Component Analysis (PCA). PCA can be used to cluster the calibration data for OPC model calibration on a two-dimensional reduction plane. PCA, in some examples, emphasizes selecting features relevant to the underlying patterns in the data. The inclusion of irrelevant or redundant features can not only slow down computation, but also introduces noise. Thus, it is beneficial to choose features from the calibration data that sufficiently represent the variability in the dataset.

In block 524, machine learning clustering is performed. In some examples, the machine learning clustering utilizes GMM. In block 526, a random sampling is taken (e.g., a given percentage), from each cluster produced by the machine learning clustering of block 524, to produce a sampled dataset. In block 528, a uniform sampling is performed on a remapped axis to supplement the sampled dataset produced in block 526, where the remapped axis is used to focus on photolithographic difficulty (e.g., photolithographically challenging test patterns). In some examples, the remapped axis is A=exp(C), where C represents cost. In some examples, C=standardized(1/Imax−Imin)+standardized(1/ILS). In block 530, an OPC model is calibrated utilizing the sampled dataset which has been supplemented with the uniform sampling on the remapped axis.

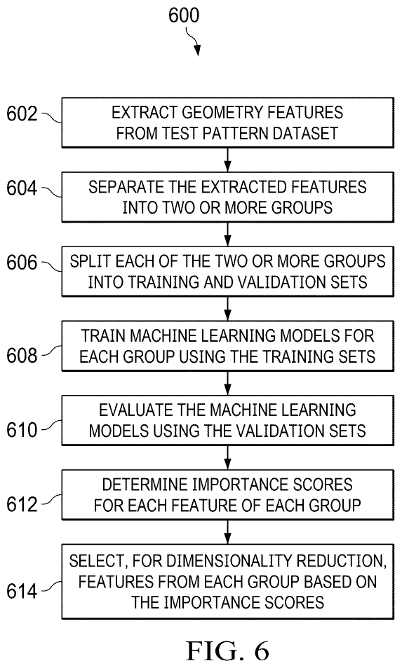

Referring now to FIG. 6, a process flow 600 for identifying geometric features used for dimensionality reduction (e.g., block 517 in FIG. 5B) will be described in further detail. The process flow 600 advantageously provides an approach for choosing features for dimensionality reduction (e.g., PCA). In some examples, the process flow 600 utilizes machine learning to select geometric features rather than manual selection of geometric features that may typically rely on the subjective domain experience of an individual performing the manual selection. In block 602, geometric features are extracted from the test pattern dataset. The extracted features are split into two or more groups in block 604. In some examples, the two or more groups include a first group without Sub-Resolution Assist Features (SRAFs) and Sub-Resolution Inverse Features (SRIFs), a second group with SRAFs, and a third group with SRIFs. By way of example only, SRAFs and SRIFs in OPC processing refer to features which are separated from targeted (main) features but assist in their printing, while not being printed themselves. In other examples, one or more other groups, such as a fourth group with SRAFs and SRIFs, may be used in addition to or in place of one or more of the first, second and third groups.

In block 606, each of the two or more groups is split into training and validation sets. In block 608, machine learning models are trained for each group using their respective training sets. The machine learning models are evaluated in block 610 using the validation set for each group. In block 612, importance scores are determined for each feature of each group. Feature selection for dimensionality reduction (e.g., block 522 in FIG. 5B) is performed in block 614, where features are selected from each group based on the importance scores.

In some examples, the machine learning models trained in block 608 include XGBoost models. XGBoost models provide predictive accuracy and versatility in tasks such as regression and classification. As an ensemble learning technique, XGBoost leverages weak learners (e.g., decision trees) to form a robust model. Predictions are derived from the cumulative contributions of all the decision trees or other weak learners, addressing errors sequentially. The objective function of an XGBoost model combines a loss function and regularization to control individual decision tree or other weak learner complexity effectively. Feature importance is evaluated based on how a feature contributes to reducing the objective function across all the decision trees or other weak learners. Higher importance scores indicate features that contribute a more significant role in reducing the objective function.

Moreover, an XGBoost algorithm iteratively builds trees, addressing the errors of previous ones and emphasizing misclassified data points. The prediction ŷᵢ for a specific instance i in XGBoost is calculated as the sum of predictions from all the trees t in the ensemble: ŷₜ=Σₜ₌₁^{T}fₜ(xᵢ), where T is the total number of trees in the ensemble and fₜ(xᵢ) is the prediction of the t-th tree for the input xᵢ. The trees are added sequentially, with each decision tree compensating for the errors of the combined ensemble up to that point. XGBoost formulates its objective function L(yᵢ, ŷₜ) as a sum of a differentiable loss function and a regularization term Π(fₜ) to control the complexity of the individual trees: Obj=Σᵢ₌₁ⁿL(yᵢ, ŷᵢ)+Σₜ₌₁^{T}Π(fₜ), where n is the number of training instances. The tree-building process involves minimizing the objective function by adding a new tree to the ensemble. For the t-th tree, the objective function is given by: Objₜ=Σᵢ₌₁ⁿL(yᵢ, ŷ_{i, t-1}+fₜ(xᵢ))+Π(fₜ), where ŷ_{i, t-1} is the sum of predictions from the first t−1 trees.

In some examples, XGBoost importance scores are utilized for feature selection alongside PCA to boost efficiency and accuracy in handling multi-dimensional datasets. Built-in feature importance scores of the XGBoost models are used to evaluate a feature's frequency of use in decision trees and its contribution to reducing prediction error. Features with substantial impact on error reduction are deemed more significant, aiding in the identification of influential features related to the label or target variable, e.g., measurement CD. In some examples, strong indicators such as mask CD and drawn CD are omitted so as to identify other potential features. Each of the two or more groups (e.g., determined in block 604) are then analyzed. As noted above, in some examples, the two or more groups include a first group without SRAFs and SRIFs, a second group with SRAFs, and a third group with SRIFs. In some examples, top features are selected from each of such groups for subsequent PCA for dimensionality reduction. In some examples, the top five geometric features from the first group without SRAFs and SRIFs are selected, and the top three geometric features from each of the second group with SRAFs and the third group with SRIFs are selected. However, in other examples, the particular number of geometric features selected from each of the two or more groups may vary.

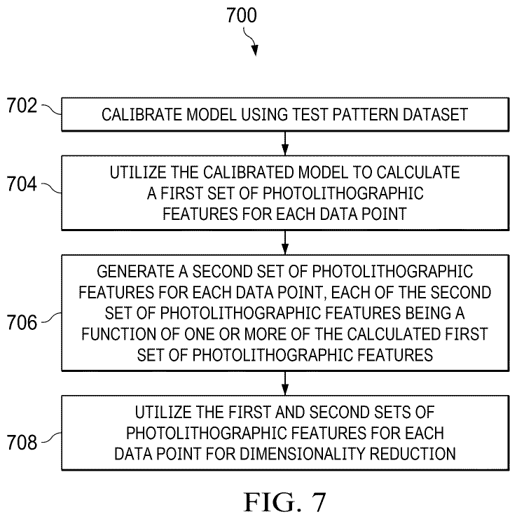

Referring now to FIG. 7, a process flow 700 for generating test pattern photolithographic indicators or features used for dimensionality reduction (e.g., block 518 in FIG. 5B) will now be described in further detail. In block 702, a model (e.g., an OPC model) is calibrated using the test pattern dataset. In block 704, the calibrated model is used to calculate a first set of photolithographic features (also referred to as indicators) for each data point. In some examples, the first set of photolithographic features include Imax, Imin and ILS. Imax and Imin represent maximum intensity and minimum intensity, respectively. Image contrast is a metric of image quality used in photography and other imaging applications, but is not directly related to photolithographic quality. ILS, representing image log slope, is a metric that describes the quality of an aerial image of incident photons. The aerial image is converted to a latent image through photolithographic processes in the photoresist. ILS is defined as the slope of the log of intensity, e.g., ILS=d(log l)/dx. In block 706, a second set of photolithographic features is generated for each data point. The second set of photolithographic features are functions of one or more of the first set of photolithographic features. In some examples, the second set of photolithographic features includes 1/(Imax−Imin), (1/(Imax−Imin))², (1/(Imax−Imin))³, 1/ILS, (1/ILS)₂, and (1/ILS)³. In block 708, the first and second sets of photolithographic features for each data point are used for dimensionality reduction (e.g., block 522 in FIG. 5B).

In addition to applying dimensionality reduction to the test patterns' geometric features, dimensionality reduction is also applied for photolithographic features or indicators. Pattern resolution is inhibited when photolithographic features such as feature contrast (e.g., Imax−Imin) and feature ILS are limited. OPC models, in some examples, are generated by leveraging the previously derived training set in order to determine the Imax, Imin and ILS of each feature within the training set. PCA transforms multi-dimensional data into linearly uncorrelated variables called principal components (PCs). PC1 captures maximum variance through a linear combination of original features, while subsequent PCs are orthogonal linear combinations capturing decreasing variance. The PCs form a reduced-dimensional representation of the data, valuable for visualization, analysis and modeling, particularly with multi-dimensional datasets.

The pitch versus cost curve may be represented as a polynomial C=aP²+bP+k, or as a higher-order polynomial. In this expression, C represents a non-dimensional cost function, which is a function of ILS, Imin, Imax, etc., and P represents pitch. Photolithographic printing may be problematic when the range [Imin, Imax] and the value of ILS are small. Therefore, the cost may be a function of 1/(Imax−Imin) as well as 1/ILS. The cost may also be a function of additional photolithographic features or indicators such as 1/(Imax−Imin), (1/(Imax−Imin))², (1/(Imax−Imin))³, 1/ILS, (1/ILS)², and (1/ILS)³.

Data preprocessing (e.g., block 520 in FIG. 5B) will now be described in further detail. Data preprocessing, in some examples, includes scaling the data (e.g., using the StandardScaler tool). For various machine learning algorithms and statistical techniques, it is desired that all features (variables) are on the same scale. Features with different scales can lead to problems during model training and evaluation. If there is a vast difference in the range, with some variables ranging in thousands and others in the tens, the machine learning algorithm may make the underlying assumption that higher ranging numbers have a greater importance. As a result, the larger variables dominate during model training. Standardization, also referred to as Z-score normalization, is a method used to transform variables so that they have a mean of 0 and a standard deviation of 1.

Dimensionality reduction (e.g., block 522 in FIG. 5B) will now be described in further detail. Dimensionality reduction, in some examples, utilizes PCA. PCA is a dimensionality reduction technique that transforms high-dimensional data into a set of linearly uncorrelated variables called principal components. The first principal component, PC1, is a linear combination of the original features selected in the dataset. PC1 is determined by assigning weights to each feature, such that PC1 captures the maximum variance in the data. Mathematically, PC1 can be expressed as: PC1=w_{1,1}·Feature₁+w_{1,2}·Feature₂+ . . . +w_{1,n}·Featureₙ, where w_{1,1}, w_{1,2}, . . . , w_{1,n} are the weights or loadings assigned to each feature. Subsequent principal components (PC2, PC3, etc.) are also linear combinations of the original features, but they are orthogonal to each other. Each principal component captures a decreasing amount of variance in the data. The principal components are ordered by the amount of variance they explain, with PC1 explaining the most variance and subsequent principal components capturing less variance. The principal components serve as reduced-dimensional representations of the original data. For example, PC1, PC2, PC3, etc. form a reduced set of variables that retain the information from the original features. This reduced representation is valuable for various tasks, including visualization, analysis and modeling, especially when dealing with high-dimensional datasets. PCA helps to focus on what is most significant in the data (e.g., reducing the amount of information without losing the significant content of the information).

PCA provides various benefits for machine learning clustering. By way of example only, with PCA, extraneous details can be removed so as to focus on the main patterns in the data. PCA also allows for visualizing the data more clearly (e.g., by creating simple graphs or charts), which helps to understand and group similar data items together. For noise reduction, consider that the data may include “noise” or random information that is not relevant. PCA can suppress the noise and find the meaningful patterns. Further, clustering algorithms work better when the data is reduced. PCA, and dimensionality reduction more generally, helps to simplify data to enable clustering algorithms to operate more effectively. Projecting any vector in an original space to a low-dimensional subspace is, in fact, linearly reducing its dimension. In machine learning clustering, the processed data uses PCA to reduce dimensionality and re-express the original high-dimensional data in a relatively lower-dimensional form. When the lower-dimensional representation is representative and able to capture most of the characteristics of the original higher-dimensional data, the set of data can be presented in a more concise way without losing any information, thus improving interpretability.

The dimensionality reduction (e.g., block 522 in FIG. 5B), in some examples, includes applying PCA with the geometric features (identified in block 517 of FIG. 5B) and the photolithographic indicators (e.g., generated in block 518 of FIG. 5B) to reduce dimensionality while preserving a majority of the variance.

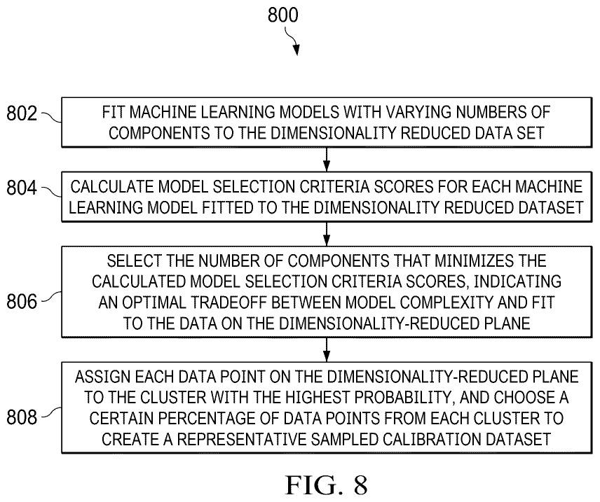

Referring now to FIG. 8, a process flow 800 for machine learning clustering (e.g., block 524 in FIG. 5B) will be described in further detail. In block 802, machine learning models with varying numbers of components are fit to the dimensionality reduced dataset. In some examples, the machine learning models are GMM models, discussed in further detail below. In block 804, model selection criteria scores (also referred to as model selection metrics) are calculated for each of the machine learning models fitted to the dimensionality reduced dataset. In some examples, the model selection criteria scores include AIC and BIC scores. In block 806, the number of components that minimize the calculated model selection criteria scores are selected, indicating an optimal or improved tradeoff between model complexity and fit to the data on the dimensionality-reduced plane. In block 808, each data point on the dimensionality-reduced plane is assigned to the cluster with the highest probability, and a certain percentage of data points from each cluster are chosen to create a representative sampled calibration dataset.

GMM in clustering enables flexible dimensionality reduction, utilizing AIC and BIC for optimal or improved component selection. GMM assumes data generation through Gaussian distributions, estimating parameters via the Expectation-Maximization (EM) algorithm, and handling complex datasets with soft assignment. The EM algorithm is utilized to estimate GMM parameters iteratively, enabling accurate data point assignment to Gaussian components. The choice of components in GMM is significant, with AIC and BIC serving as criteria for balancing complexity and goodness-of-fit. Lower AIC and BIC values in model selection ensure a better balance, enhancing the reliability of GMMs in applications such as clustering and density estimation. After GMM clustering, data points are selected (e.g., randomly) at a specified percentage from each cluster for OPC model calibration. In some examples, 80% is chosen as the sampling percentage from the training set.

GMM provides clustering and density estimation, and is particularly effective in processing complex datasets with multiple patterns. In some examples, GMM assumes that the dataset is generated by a mixture of several Gaussian distributions, each characterized by its mean, covariance matrix and weight. This model is particularly effective when dealing with complex datasets that exhibit multiple underlying patterns. Consider a dataset X with N data points and K Gaussian components. The probability density function (PDF) of the GMM is expressed as: P(X)=Σₖ₌₁^{T}πₖ·N(X|μₖ, Σₖ), where πₖ represents the weight of the k-th Gaussian component, satisfying Σₖ₌₁^{K}πₖ=1. N(X|μₖ, Σₖ) is the Gaussian distribution with mean μₖ and covariance matrix Σₖ. The parameters πₖ, μₖ, and Σₖ are estimated through the EM algorithm, which iteratively maximizes the likelihood of the observed data. The first step of EM is the E-step (Expectation) to compute the posterior probabilities (responsibilities) of each data point belonging to each Gaussian component. The second step of EM is the M-step (Maximization) to update the parameters πₖ, μₖ, and Σₖ based on the computed responsibilities. GMM clustering provides a way to group similar data together. GMM helps to find the groups, but is more flexible than simply placing each data point in one group. Instead, GMM allows for calculating the chance or probability that each data point belongs to multiple groups (e.g., 70% chance of belonging to Group A, 30% chance of belonging to Group B). GMM thus provides an advantageous way to group data, allowing for some uncertainty and flexibility.

GMM clustering begins with initializing the Gaussian distributions. The first step in the EM algorithms for GMM clustering is to initialize the Gaussian distributions, so initial values are given to each Gaussian distribution by picking random data points, a random mean and a random variance (e.g., the standard deviation squared). The second step is to soft cluster the data points, which is the “Expectation” or E-step of the EM algorithm. This is basically the PDF of a normal distribution, and includes calculating the probability that each data point belongs to each cluster. The third step is to re-estimate the parameters of the Gaussian distributions, which is the “Maximization” or M-step of the EM algorithm. This step includes taking the result of the second step (e.g., the memberships of all the data points to all the clusters) and using this to produce new mean and variance values for the Gaussian distributions. This will be repeated until the clustering mean and variance do not change (e.g., convergence).

After parameter estimation, GMM assigns each data point to the Gaussian component with the highest posterior probability. This probabilistic assignment allows GMM to capture complex structures, handle overlapping clusters, and provide a soft assignment of data points. Selecting the optimal number of components in a GMM in unsupervised learning should strike a balance between complexity and goodness-of-fit. AIC and BIC are information-theoretic criteria for this selection process. The sum of AIC and BIC provides a comprehensive measure to determine the optimal number of components in a GMM by considering both goodness-of-fit and complexity. Lower AIC and BIC values indicate a better model fit.

The AIC is formulated as: AIC=−2*Log−Likelihood+2*Number_of_Parameters, where Log-Likelihood quantifies how well the model explains the observed data, and the penalty term (2*Number_of_Parameters) penalizes for model complexity. The lower the AIC, the better the model. The principle behind AIC is to find a model that effectively explains the data while penalizing model complexity. AIC encourages the selection of a model that minimizes the information loss. In the context of GMM clustering, AIC can be used to select the optimal number of Gaussian components, where lower AIC values indicate a better model fit. AIC gives each model a score, and the lower the score, the better the model is at explaining the data. In GMM clustering, AIC helps to decide how many groups (clusters) to create, looking for the right balance between fitting the data well and keeping the model simple.

The BIC is formulated as: BIC=−2*Log−Likelihood+log(N)*Number_of_Parameters. Similar to AIC, the BIC includes a penalty term (e.g., log(N)*Number_of_Parameters) that increases with the number of parameters. The penalty term for BIC penalizes more severely for model complexity compared to AIC, especially with larger datasets. Similar to AIC, BIC can be used to select the optimal number of Gaussian components, where lower BIC values indicated a better model fit. BIC scores models such as AIC, but it gives higher penalties for complexity. In GMM clustering, BIC helps to decide the right number of clusters by emphasizing simplicity even more than AIC.

The sum of AIC and BIC, e.g., AIC+BIC, is utilized for model selection by considering both criteria simultaneously. In some examples, models which demonstrate a tradeoff between goodness-of-fit and simplicity are preferred. Lower AIC+BIC values suggest a better balance, with the model having the minimum AIC+BIC considered the most appropriate. The combined AIC and BIC scores offer a robust method for selecting the optimal number of components in a GMM, ensuring effective capturing of underlying data structure without overfitting. This approach enhances the reliability and interpretability of GMMs across applications such as clustering and density estimation.

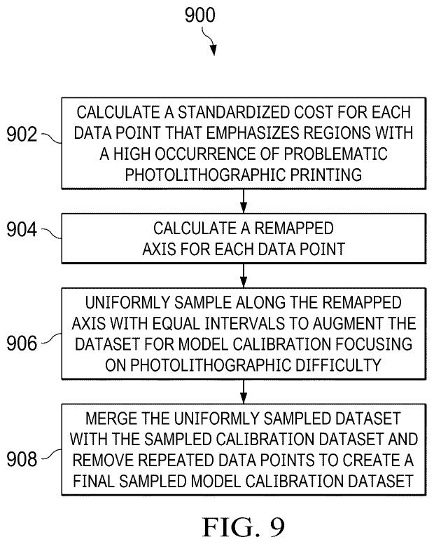

Referring now to FIG. 9, a process flow 900 for sampling uniformly in a remapped axis to supplement the sampled dataset (e.g., block 528 in FIG. 5B) will now be described in detail. In addition to sampling from each cluster for generalization (e.g., block 526 in FIG. 5B), the process flow 900 is used to implement uniform sampling along a remapped axis to supplement the sampled dataset (in some examples, the GMM-clustered OPC model calibration dataset) with additional features that are challenging to resolve photolithographically. This approach ensures a more comprehensive coverage of photolithographic difficulty for sampled test patterns. By emphasizing regions with a high occurrence of problematic photolithographic printing, the sampled dataset is complemented with a particular focus on photolithographic difficulty. Problematic photolithographic printing may arise when the range of maximum to minimum intensity, [Imax, Imin], and the value of ILS are small (e.g., below respective designated threshold values). In block 902, a standardized cost for each data point that emphasizes regions with a high occurrence of problematic photolithographic printing is calculated. In some examples, block 902 includes utilizing the Python sklearn StandardScaler( ) function to calculate a standardized(1/(Imax−Imin)) and standardized(1/ILS) as the cost C for each data point.

In block 904, a remapped axis is calculated for each data point. In some examples, the remapped axis is P′=A−exp(C), where A is a constant amplitude to determine the initial value, and C is the cost. P′ is the warped version of pitch (P). Sampling uniformly in P′ stretches the P axis, emphasizing areas where the cost is large. P′=A−exp(C)≈(A−1)−C−C2/2−C3/3! (e.g., Taylor Series Expansions of Exponential Functions). In block 906, uniform sampling along the remapped axis with equal intervals is performed to augment the dataset for model calibration focusing on photolithographic difficulty. Higher values of the cost parameter correspond to increased difficulty in photolithographic printing processes. According to the equation, a larger C leads to a faster decay of P′. Consequently, traversing along the P′ axis with uniform intervals, indicating identical changes in P′ for each step, results in more frequent sampling along the C axis where C is significant, and less frequent sampling where C is minimal. In other words, uniformly sampling along P′ will sample more densely where the cost C is large. This is because the differential change in P′ depends on the value of C through the exponential function exp(C). The uniform sampling in P′ provides a balanced sampling strategy for balanced sampling across photolithographic difficulty levels, enhancing the OPC model calibration for real-world photolithographic scenarios. In block 908, the uniformly sampled dataset from block 906 is merged with the sampled calibration dataset (e.g., from block 526 of FIG. 5B), and any repeated data points are removed to create the final sampled model calibration dataset (e.g., for OPC model calibration).

In some examples, model verification is performed for a calibrated OPC model. Various model metrics may be used for model verification, including a cost function, Root Mean Square Error (RMSE), range, and a coefficient of determination or R2 value. The cost function guides model regression optimization, aiming to minimize discrepancies between predicted and measured CD, where a lower value indicates a better result. RMSE is calculated according to

$$RMSE = \sqrt{\frac{1}{n} {\sum }_{i} {x}_{i}^{2}} ,$$

where n is the number of calibration data points and xᵢ is the model's predicted CD minus the measured CD. A lower RMSE value indicates a better result. The range is (the maximum of the model's predicted CD minus the measured CD) minus (the minimum of the model's predicted CD minus the measured CD). A lower range indicates a better result. The R2 value tests the OPC model stability in diverse design environments, measuring its ability to predict contour changes from perturbations. A higher R2 value indicates better performance.

The machine learning-driven model calibration (e.g., block 506 in FIG. 5), in some examples, helps to optimize test pattern sampling to minimize OPC model calibration time while ensuring accurate prediction. Further, the incorporation of photolithographic features (e.g., 1/(Imax−Imin), 1/ILS, etc.) significantly enhances prediction accuracy. Model convergence is further improved with remapped axis sampling. The remapped axis is used to sample more in areas where photolithographic difficulty occurs, which leads to improved model convergence and prediction accuracy. The machine learning-driven model calibration thus provides significant improvements in terms of model accuracy and cycle time for OPC development.

In some examples, dimensionality reduction (e.g., block 522 in FIG. 5B) may leverage neural networks, such as Variational Autoencoders (VAEs) or shallow learning techniques, to enhance interpretability and performance on complex, non-linear data. Such exploration may improve the effectiveness of dimensionality reduction. Further, the machine learning clustering (e.g., block 524 in FIG. 5B) may incorporate K-means clustering as a precursor to GMM, replacing random initialization. The incorporation of K-means clustering may expedite convergence and enhance solution quality.

In some examples, rather than manually selecting geometric features (e.g., mask CD, pitch, etc.) for dimensionality reduction, XGBoost is used to identify significant features affecting the target variable (e.g., measurement CD). XGBoost advantageously provides a built-in feature importance score, calculated based on each feature's contribution to prediction error reduction. Features frequently used and with substantial impact on prediction error reduction are considered for inclusion in the sampling method. These prediction errors represent the differences between the predicted values and the actual values of the target variable (e.g., measurement CD) using the analyzed features (e.g., mask CD, pitch, etc.).

In some examples, instead of utilizing photolithographic features such as Imax, Imin, and ILS directly for dimensionality reduction, derived photolithographic features calculated based on such empirical photolithographic features are used, such as pitch², pitch³, 1/(Imax−Imin), 1/(Imax−Imin)², 1/(Imax−Imin)³, 1/ILS, 1/ILS², and 1/ILS³. This is based on the observation that the pitch versus cost curve can be represented as a polynomial: C=P2+b*P+k, where P represents pitch and C represents cost, where the cost is a function of photolithographic indicators such as ILS, Imin, Imax, etc. Thus, these additional features account for the behavior of cost in relation to these photolithographic indicators.

For clustering, GMM is used in some examples. As mentioned, GMM is a probabilistic model that offers enhanced flexibility and insights into cluster characteristics in the dimensionality reduction plane. The selection of the appropriate number of clusters is determined, in some examples, using model selection metrics such as the sum of AIC and BIC. In addition to sampling from each cluster, some examples implement uniform sampling in a remapped axis to augment the sampled test patterns, with a focus on photolithographic difficulty emphasizing regions with high costs. The remapped axis is defined as P′=A−exp(C), where C represent the cost (e.g., standardized(1/(Imax−Imin))+standardized(1/ILS)). This allows for a more comprehensive coverage of photolithographic difficulty for sampled test patterns, based on pitch versus cost observations.

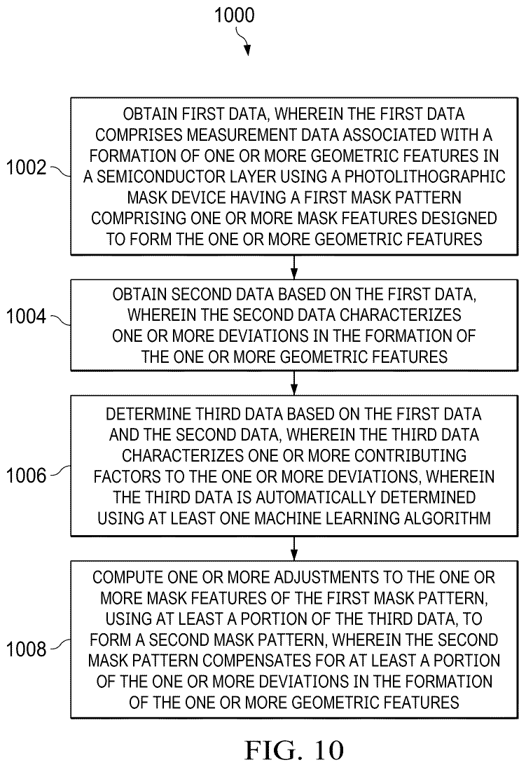

Referring now to FIG. 10, a process flow 1000 for computing adjustments to mask features of mask patterns will be described. In block 1002, first data is obtained, where the first data includes measurement data associated with a formation of one or more geometric features in a semiconductor layer using a photolithographic mask device, where the photolithographic mask device has a first mask pattern including one or more mask features designed to form the one or more geometric features. In block 1004, second data is obtained based on the first data, where the second data characterizes one or more deviations in the formation of the one or more geometric features using the photolithographic mask device having the first mask pattern.

In block 1006, third data is determined, automatically using at least one machine learning algorithm, based on the first data and the second data. The third data characterizes one or more contributing factors to the one or more deviations. Block 1006, in some examples, includes applying a dimensionality reduction process (e.g., PCA) to the first data and the second data.

Block 1006, in some examples, further includes applying a gradient boosting algorithm (e.g., XGBoost) to select a subset of the one or more geometric features prior to applying the dimensionality reduction process. Applying the gradient boosting algorithm, in some examples, includes: separating the one or more geometric features into two or more groups; generating, for each of the two or more groups, a gradient boosting machine learning model; determining, utilizing the generated gradient boosting machine learning models, importance scores for each of the one or more geometric features; and selecting, from each of the two or more groups, at least one geometric feature for inclusion in the subset of the one or more geometric features. The two or more groups may include a first group of geometric features without SRAFs and SRIFs, a second group of geometric features with SRAFs, and a third group of geometric features with SRIFs.

Block 1006, in some examples, includes identifying one or more photolithographic indicators prior to applying the dimensionality reduction process. Identifying the one or more photolithographic indicators, in some examples, includes calculating one or more photolithographic metrics based on the first data and the second data, and generating at least one of the one or more photolithographic indicators as a function of at least one of the calculated one or more photolithographic metrics. The calculated one or more photolithographic metrics, in some examples, include Imax, Imin and ILS.

In some examples, block 1006 includes applying a GMM-based clustering process to the dimensionality-reduced dataset. Applying the GMM-based clustering process, in some examples, includes: fitting two or more GMMs with varying numbers of components to the dimensionality-reduced dataset; calculating model selection criteria scores for each of the two or more GMMs; selecting a number of clusters based on the calculated model selection criteria scores; assigning data points in the dimensionality-reduced dataset to the clusters; and generating a sampled dataset by selecting, from each of the clusters, one or more of the data points assigned to that cluster.

Block 1006, in some examples, includes applying a first sampling process to results of the GMM-based clustering process, where the first sampling process is a random sampling process. Block 1006, in some examples, further includes applying a second sampling process to results of the first sampling process, where the second sampling process is a uniform sampling process with respect to one or more photolithographic indicators characterizing difficulty of photolithographic processing. The second sampling process, in some examples, includes: calculating a standardized cost for each data point in the first data and the second data based on standardized photolithographic indicator metrics calculated for each data point; determining a remapped axis, where the remapped axis is a remapping of a pitch metric that emphasizes photolithographic difficulty where at least one of (i) a range of Imax and Imin is below a first designated threshold and (ii) an ILS value is below a second designated threshold; and sampling data points from the first data and the second data uniformly along the remapped axis.

In block 1008, one or more adjustments to the one or more mask features of the first pattern are computed, using at least a portion of the third data, to generate a second mask pattern. The second mask pattern compensates for at least a portion of the one or more deviations in the formation of the one or more geometric features. In some examples, block 1008 includes using at least a portion of the third data to calibrate an OPC model, and executing an OPC process using the calibrated OPC model to compute the one or more adjustments to the one or more mask features of the first mask pattern. In some examples, a method of fabricating a semiconductor device includes forming, utilizing a photolithographic mask device having the second mask pattern, the one or more geometric features in a semiconductor layer.

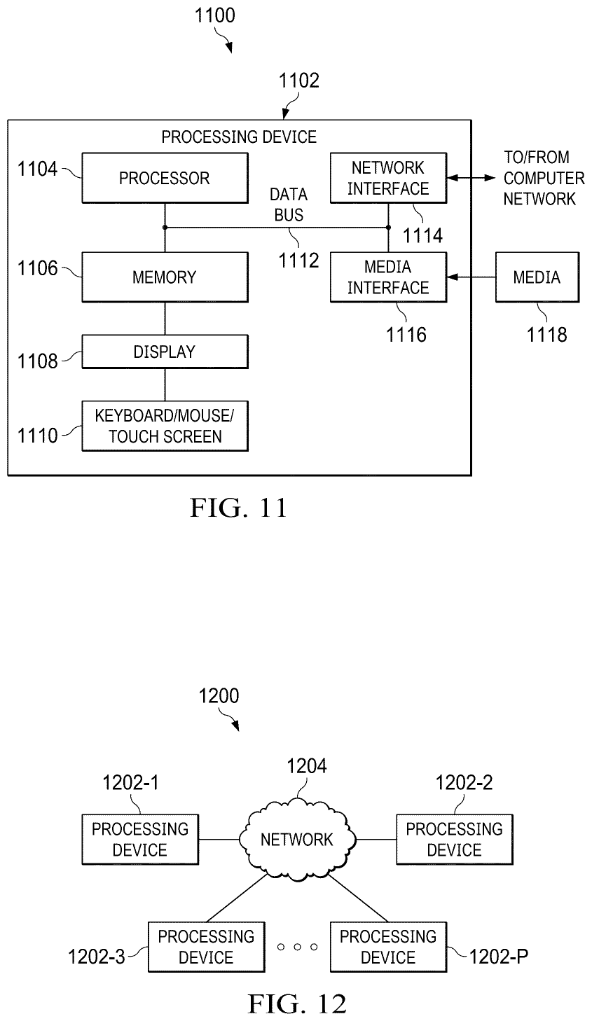

Referring now to FIG. 11, a computer system 1100 in accordance with which one or more examples can be implemented is illustrated. That is, one, more than one, or all of the components and/or functionalities shown and described in the context of FIGS. 1-10 can be implemented via the computer system 1100 depicted in FIG. 11. In some examples, computer system 1100 may be implemented with the CAD system and/or pattern applying tool described above in the context of FIG. 1.

More particularly, FIG. 11 shows a processing device 1102 including a processor 1104, a memory 1106, and an input/output (I/O) interface formed by a display 1108 and a keyboard/mouse/touchscreen 1110. Other I/O devices may be part of the I/O interface. The processor 1104, memory 1106 and I/O interface are interconnected via data bus 1112 as part of the processing device 1102 (e.g., a computer, workstation, server, client device, etc.). Interconnections via data bus 1112 are also provided to a network interface 1114 and a media interface 1116. Network interface 1114 (which can include, for example, transceivers, modems, routers and the like) enables the system to couple to other processing systems or devices (such as remote displays or other computing and storage devices) through intervening private and/or public computer networks (wired and/or wireless). Media interface 1116 (which can include, for example, a removable disk drive) interfaces with media 1118.

The processor 1104 can include, for example, a central processing unit (CPU), a graphical processing unit (GPU), a microprocessor, a microcontroller, an application-specific integrated circuit (ASIC), a field programmable gate array (FPGA) or other type of processing circuitry, as well as portions or combinations of such circuitry elements. Components of systems as disclosed herein can be implemented at least in part in the form of one or more software programs stored in memory and executed by a processor of a processing device such as processing device 1102. Memory 1106 (or another storage device) having such program code embodied therein is an example of what is more generally referred to herein as a processor-readable storage medium. Articles of manufacture may include such processor-readable storage media. A given such article of manufacture may include, for example, a storage device such as a storage disk, a storage array or an integrated circuit containing memory. The term article of manufacture as used herein should be understood to exclude transitory, propagating signals.

Furthermore, memory 1106 may include electronic memory such as random access memory (RAM), read-only memory (ROM) or other types of memory, in any combination. The one or more software programs when executed by the processing device 1102 causes the device to perform functions associated with one or more of the components/steps of systems/methodologies in FIGS. 1-10. Other examples of processor-readable storage media may include, for example, optical or magnetic disks.

Still further, the I/O interface formed by devices 1108 and 1110 is used for inputting data to the processor 1104 and for providing initial, intermediate and/or final results associated with the processor 1104.

Referring now to FIG. 12, a processing platform 1200 in accordance with which one or more examples can be implemented is shown. FIG. 12 shows a distributed communications/computing network that includes a plurality of processing devices 1202-1 through 1202-P (herein collectively referred to as processing devices 1202) configured to communicate with one another over a network 1204.

In some examples, one or more of processing devices 1202 in FIG. 12 may be configured in a manner similar to that of processing device 1102 of FIG. 11. The methodologies described herein may be executed in one such processing device 1202, or executed in a distributed manner across two or more of such processing devices 1202. Moreover, a server, a client device, a processing unit or any other processing platform element may be viewed as an example of what is more generally referred to herein as a processing device. The network 1204 may include, for example, a global computer network such as the Internet, a wide area network (WAN), a local area network (LAN), a satellite network, a telephone or cable network, or various portions or combinations of these and other types of networks (including wired and/or wireless networks).

As described herein, the processing devices 1202 may represent a large variety of devices. For example, the processing devices 1202 can include a portable device such as a mobile telephone, a smart phone, personal digital assistant (PDA), tablet, computer, a client device, etc. The processing devices 1202 may alternatively include a desktop or laptop personal computer, a server, a microcomputer, a workstation, a mainframe computer, or any other information processing device which can implement any or all of the techniques detailed in accordance with one or more examples. Processing device 1202, in some examples, may include a CAD system or the like, and may otherwise be part of a mask design system and/or a semiconductor fabrication system.

One or more of the processing devices 1202 may also be considered a user. The term user, as used in this context, encompasses, by way of example and without limitation, a user device, a person utilizing or otherwise associated with the device, or a combination of both. An operation described herein as being performed by a user may therefore, for example, be performed by a user device, a person utilizing or otherwise associated with the device, or by a combination of both the person and the device, the context of which is apparent from the description.

Additionally, as noted herein, one or more modules, elements or components described in connection with examples can be located geographically-remote from one or more other modules, elements or components. That is, for example, the modules, elements or components shown and described in the systems and methodologies of context of FIGS. 1-10 can be distributed in an Internet-based environment, a mobile telephony-based environment and/or a local area network environment. The systems described herein are not limited to any particular one of these implementation environments. However, depending on the operations being performed by the system, one implementation environment may have some functional and/or physical benefits over another implementation environment.

The processing platform 1200 shown in FIG. 12 may include additional components such as parallel processing systems, physical machines, virtual machines, virtual switches, storage volumes, etc. Again, the particular processing platform shown in this figure is presented by way of example only, and may include additional or alternative processing platforms, as well as numerous distinct processing platforms in any combination. Also, numerous other arrangements of servers, clients, computers, storage devices or other components are contemplated in processing platform 1200.

Furthermore, the processing platform 1200 of FIG. 12 can include virtual machines (VMs) implemented using a hypervisor. A hypervisor is an example of what is more generally referred to herein as virtualization infrastructure. The hypervisor runs on physical infrastructure. As such, the techniques illustratively described herein can be provided in accordance with one or more cloud services. The cloud services thus run on respective ones of the virtual machines under the control of the hypervisor. Processing platform 1200 may also include multiple hypervisors, each running on its own physical infrastructure. Portions of that physical infrastructure might be virtualized.

Virtual machines are logical processing elements that may be instantiated on one or more physical processing elements (e.g., servers, computers, processing devices). That is, a virtual machine generally refers to a software implementation of a machine (i.e., a computer) that executes programs like a physical machine. Thus, different virtual machines can run different operating systems and multiple applications on the same physical computer. Virtualization is implemented by the hypervisor which is directly inserted on top of the computer hardware in order to allocate hardware resources of the physical computer dynamically and transparently. The hypervisor affords the ability for multiple operating systems to run concurrently on a single physical computer and share hardware resources with each other.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method, comprising:
obtaining first data, wherein the first data comprises measurement data associated with a formation of one or more geometric features in a semiconductor layer using a photolithographic mask device, the photolithographic mask device having a first mask pattern comprising one or more mask features designed to form the one or more geometric features;
obtaining second data based on the first data, wherein the second data characterizes one or more deviations in the formation of the one or more geometric features;
determining third data based on the first data and the second data, wherein the third data characterizes one or more contributing factors to the one or more deviations, wherein the third data is automatically determined using at least one machine learning algorithm; and
computing one or more adjustments to the one or more mask features of the first mask pattern, using at least a portion of the third data, to generate a second mask pattern, wherein the second mask pattern compensates for at least a portion of the one or more deviations in the formation of the one or more geometric features.

2. The method of claim 1, wherein computing the one or more adjustments to the one or more mask features of the first mask pattern comprises:
using at least a portion of the third data to calibrate an optical proximity correction model; and
using the calibrated optical proximity correction model to tune a corresponding optical proximity correction process to compute the one or more adjustments to the one or more mask features of the first mask pattern.

3. The method of claim 1, wherein determining the third data further comprises applying a dimensionality reduction process to the first data and the second data to generate a dimensionality-reduced dataset.

4. The method of claim 3, wherein determining the third data further comprises applying a gradient boosting algorithm to select a subset of the one or more geometric features prior to applying the dimensionality reduction process.

5. The method of claim 4, wherein applying the gradient boosting algorithm comprises:
separating the one or more geometric features into two or more groups;
generating, for each of the two or more groups, a gradient boosting machine learning model;
determining, utilizing the generated gradient boosting machine learning models, importance scores for each of the one or more geometric features; and
selecting, from each of the two or more groups, at least one geometric feature for inclusion in the subset of the one or more geometric features.

6. The method of claim 5, wherein the two or more groups comprise:
a first group of geometric features without sub-resolution assist features and sub-resolution inverse features;
a second group of geometric features with sub-resolution assist features; and
a third group of geometric features with sub-resolution inverse features.

7. The method of claim 3, wherein determining the third data further comprises identifying one or more photolithographic indicators prior to applying the dimensionality reduction process.

8. The method of claim 7, wherein identifying the one or more photolithographic indicators comprises:
calculating one or more photolithographic metrics based on the first data and the second data; and
generating at least one of the one or more photolithographic indicators as a function of at least one of the calculated one or more photolithographic metrics.

9. The method of claim 8, wherein the calculated one or more photolithographic metrics comprise maximum intensity, minimum intensity and image log slope.

10. The method of claim 3, wherein determining the third data further comprises applying a Gaussian mixture model-based clustering process to the dimensionality-reduced dataset.

11. The method of claim 10, wherein applying the Gaussian mixture model-based clustering process comprises:
fitting two or more Gaussian mixture models with varying numbers of components to the dimensionality-reduced dataset;
calculating model selection criteria scores for each of the two or more Gaussian mixture models;
selecting a number of clusters based on the calculated model selection criteria scores;
assigning data points in the dimensionality-reduced dataset to the clusters; and
generating a sampled dataset by selecting, from each of the clusters, one or more of the data points assigned to that cluster.

12. The method of claim 10, wherein determining the third data further comprises applying a first sampling process to results of the Gaussian mixture model-based clustering process, wherein the first sampling process comprises a random sampling process.

13. The method of claim 12, wherein determining the third data further comprises applying a second sampling process to results of the first sampling process, wherein the second sampling process comprises a uniform sampling process with respect to one or more photolithographic indicators characterizing difficulty of photolithographic processing.

14. The method of claim 13, wherein the second sampling process comprises:
calculating a standardized cost for each data point in the first data and the second data based on standardized photolithographic indicator metrics calculated for each data point;
determining a remapped axis, the remapped axis being a remapping of a pitch metric that emphasizes photolithographic difficulty where at least one of (i) a range of the maximum intensity and minimum intensity is below a first designated threshold and (ii) an image log slope value is below a second designated threshold; and
sampling data points from the first data and the second data uniformly along the remapped axis.

15. A mask device comprising the second mask pattern generated utilizing the method of claim 1.

16. An apparatus, comprising:
at least one processor; and
at least one memory storing instructions that, when executed by the at least one processor, cause the apparatus at least to:
obtain first data, wherein the first data comprises measurement data associated with a formation of one or more geometric features in a semiconductor layer using a photolithographic mask device, the photolithographic mask device having a first mask pattern comprising one or more mask features designed to form the one or more geometric features;
obtain second data based on the first data, wherein the second data characterizes one or more deviations in the formation of the one or more geometric features;
determine third data based on the first data and the second data, wherein the third data characterizes one or more contributing factors to the one or more deviations, wherein the third data is automatically determined using at least one machine learning algorithm; and
compute one or more adjustments to the one or more mask features of the first mask pattern, using at least a portion of the third data, to generate a second mask pattern, wherein the second mask pattern compensates for at least a portion of the one or more deviations in the formation of the one or more geometric features.

17. The apparatus of claim 16, wherein computing the one or more adjustments to the one or more mask features of the first mask pattern further comprises:
using at least a portion of the third data to calibrate an optical proximity correction model; and
using the calibrated optical proximity correction model to tune a corresponding optical proximity correction process to compute the one or more adjustments to the one or more mask features of the first mask pattern.

18. The apparatus of claim 16, wherein determining the third data comprises:
applying a gradient boosting algorithm to select a subset of the one or more geometric features;
identifying one or more photolithographic indicators based on the second data;
applying a Gaussian mixture model-based clustering process to a dataset comprising the selected subset of the one or more geometric features and the identified one or more photolithographic indicators;
applying a first sampling process to results of the Gaussian mixture model-based clustering process, wherein the first sampling process comprises a random sampling process; and
applying a second sampling process to results of the first sampling process, wherein the second sampling process comprises a uniform sampling process with respect to one or more photolithographic indicators characterizing difficulty of photolithographic processing.

19. A method of fabricating a semiconductor device, comprising:
determining, based on (i) first data comprising measurement data associated with formation of one or more geometric features using a first mask pattern comprising one or more mask features and (ii) second data characterizing one or more deviations in the formation of the one or more geometric features using the first mask pattern, third data utilizing at least one machine learning algorithm, the third data characterizing one or more contributing factors to the one or more deviations;
calibrating an optical proximity correction model based on the third data;
using the calibrated optical proximity correction model to tune a corresponding optical proximity correction process to compute one or more adjustments to the one or more mask features of the first mask pattern to form a second mask pattern, the second mask pattern compensating for at least a portion of the one or more deviations in the formation of the one or more geometric features using the first mask pattern; and
forming the one or more geometric features in a semiconductor layer utilizing a photolithographic mask device having the second mask pattern.

20. The method of claim 19, wherein determining the third data comprises:
applying a gradient boosting algorithm to select a subset of the one or more geometric features;
identifying one or more photolithographic indicators based on the second data;
applying a Gaussian mixture model-based clustering process to a dataset comprising the selected subset of the one or more geometric features and the identified one or more photolithographic indicators;
applying a first sampling process to results of the Gaussian mixture model-based clustering process, wherein the first sampling process comprises a random sampling process; and
applying a second sampling process to results of the first sampling process, wherein the second sampling process comprises a uniform sampling process with respect to one or more photolithographic indicators characterizing difficulty of photolithographic processing.

21. A semiconductor device comprising the semiconductor layer with the one or more geometric features formed utilizing the method of claim 19.
